(19) United States
(12) Patent Application Publication
(10) Pub. No.: US 2024/0222388 A1
(43) Pub. Date: Jul. 4, 2024

(54) Display Device

(71) Applicant: LG Display Co., Ltd., Seoul (KR)

(72) Inventors: JaeHyung Jo, Goyang-si (KR); WonHo Lee, Paju-si (KR); Wondoo Kim, Gimpo-si (KR)

(21) Appl. No.: 18/491,139

(22) Filed: Oct. 20, 2023

(30) Foreign Application Priority Data
Dec. 29, 2022 (KR) 10-2022-0188780

(51) Int. Cl. H01L 27/12; H01L 25/16

(52) U.S. Cl. CPC H01L 27/124; H01L 25/167

(57) ABSTRACT

A display device includes a display panel including a plurality of pixels is disposed; a data driver configured to supply a data signal to the pixels; and a gate driver configured to supply a gate signal to the pixels. The panel circuit includes: a plurality of data lines configured to supply the data signal to the pixels; a plurality of gate lines configured to supply the gate signal to the pixels; a high potential voltage line configured to supply a high potential voltage to the pixels; and a reference voltage line configured to supply a reference voltage to the pixels, and the high potential voltage line and the reference voltage line are between a first emission area and a second emission area of each of a plurality of sub pixels included in at least a first pixel of the plurality of pixels.

### CROSS-REFERENCE TO RELATED APPLICATION

This application claims the priority of Republic of Korea Patent Application No. 10-2022-0188780 filed on Dec. 29, 2022, in the Korean Intellectual Property Office, which is incorporated by reference in its entirety.

### BACKGROUND

### Field

The present disclosure relates to a display device.

### Description of the Related Art

The display device may include a display panel including a plurality of sub pixels and a driver for driving the display panel. The driver includes a gate driver configured to supply a gate signal to the display panel and a data driver configured to supply a data signal. When a signal, such as a gate signal and a data signal, is supplied to a sub pixel included in the display panel, a selected sub pixel emits light to display images. In recent years, as the size of the display panel is increased, in order to smoothly drive the display panel, the display panel is driven in a double rate driving (DRD) manner which increases a driving frequency.

### SUMMARY

An object to be achieved by the present disclosure is a display device which reduces data delay caused by a bundle of data lines, on a line structure in which some of data lines are bundled to implement a DRD driving method.

Another object to be achieved by the present disclosure is to provide a display device which timely creates a driving signal representing black.

Still another object to be achieved by the present disclosure is to provide a display device which suppresses complete darkening of a sub pixel in which short-circuit is caused, when short-circuit is generated between a pixel electrode and a common electrode.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device includes a display panel including a plurality of pixels; a data driver configured to supply a data signal to the plurality of pixels; and a gate driver configured to supply a gate signal to the plurality of pixels. The panel circuit includes: a plurality of data lines configured to supply the data signal to the plurality of pixels; a plurality of gate lines configured to supply the gate signal to the plurality of pixels; a high potential voltage line configured to supply a high potential voltage to the plurality of pixels; and a reference voltage line configured to supply a reference voltage to the plurality of pixels, and the high potential voltage line and the reference voltage line are between a first emission area and a second emission area of each of a plurality of sub pixels included in at least a first pixel of the plurality of pixels.

A display device, comprising: a display panel including a plurality of pixels, a high potential voltage line configured to supply a high potential voltage to the plurality of pixels, and a reference voltage line configured to supply a reference voltage to the plurality of pixels; a data driver configured to supply data signals to the plurality of pixels; and a gate driver configured to supply gate signals to the plurality of pixels, wherein a pixel from the plurality of pixels includes a plurality of sub pixels configured to emit different colors of light, each sub pixel including a first emission area and a second emission area that is electrically connected to the first emission area and emits a same color of light as the first emission area, wherein the reference voltage line and the high potential voltage line are between the first emission area and the second emission area of each of the plurality of sub pixels of the pixel in a plan view of the display device.

Other detailed matters of the exemplary embodiments are included in the detailed description and the drawings.

According to the exemplary embodiment of the present disclosure, in the display device, the bundle of data lines is not present so that the data delay is not generated.

Further, according to the exemplary embodiment of the present disclosure, in the display device, data delay is suppressed so that a data signal corresponding to black may be generated.

Further, according to the exemplary embodiment of the present disclosure, in the display device, a pixel electrode includes a bridge for connecting emission areas of sub pixels which are spatially separated. Therefore, when a dark spot is generated in some of the emission areas, the bridge is disconnected to suppress the dark spot from being generated in the remaining emission areas.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a display device according to an exemplary embodiment of the present disclosure;

FIG. 2 is a circuit diagram illustrating an example of a sub pixel included in a display device according to an exemplary embodiment;

FIG. 3 is a block diagram for explaining one example of a placement relationship of sub pixels included in a display device according to an exemplary embodiment;

FIG. 4A is a layout for explaining one example of a placement relationship of sub pixels included in a display device according to an exemplary embodiment;

FIG. 4B is a referential view for explaining an example of an output of a first sub pixel of display device according to an exemplary embodiment;

FIG. 4C is a view illustrating an example that a display device transmits a data signal to sub pixel(s) according to an exemplary embodiment;

FIG. 5 is a view for explaining an example that a display device drives a solid screen according to an exemplary embodiment; and

FIGS. 6 to 8 are views for explaining examples that a display device drives a horizontal one-by-one driving screen, a vertical one-by-one driving screen, and a dot driving screen according to an exemplary embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

A transistor used for a display device according to exemplary embodiments of the present disclosure may be implemented by any one transistor of n-channel transistors (NMOS) and p-channel transistors (PMOS). The transistor may be implemented by an oxide semiconductor transistor having an oxide semiconductor as an active layer or an LTPS transistor having a low temperature poly-silicon (LTPS) as an active layer. The transistor may include at least a gate electrode, a source electrode, and a drain electrode. The transistor may be implemented as a thin film transistor on a display panel. In the transistor, carriers flow from the source electrode to the drain electrode. In the case of the n-channel transistor NMOS, since the carriers are electrons, in order to allow the electrons to flow from the source electrode to the drain electrode, a source voltage may be lower than a drain voltage. The current in the n-channel transistor NMOS flows from the drain electrode to the source electrode and the source electrode may serve as an output terminal. In the case of the p-channel transistor (PMOS), since the carriers are holes, in order to allow the holes to flow from the source electrode to the drain electrode, a source voltage is higher than a drain voltage. In the p-channel transistor PMOS, the holes flow from the source electrode to the drain electrode so that current flows from the source to the drain and the drain electrode serves as an output terminal. Accordingly, the source and the drain may be switched in accordance with the applied voltage so that it should be noted that the source and the drain of the transistor are not fixed. In the present specification, it is assumed that the transistor is an n-channel transistor NMOS, but is not limited thereto so that the p-channel transistor may be used and thus a circuit configuration may be changed.

A gate signal of transistors which are used as switching elements swings between a gate-on voltage and a gate-off voltage. The gate on voltage is set to be higher than a threshold voltage Vth of the transistor and the gate off voltage is set to be lower than the threshold voltage Vth of the transistor. The transistor is turned on in response to the gate-on voltage and is turned off in response to the gate-off voltage. In the case of the n-channel transistor NMOS, the gate-on voltage is a gate high voltage VGH and the gate-off voltage is a gate low voltage VGL. In the case of the p-channel transistor PMOS, the gate on voltage is a gate low voltage VGL and the gate off voltage is a gate high voltage VGH.

Hereinafter, various exemplary embodiments of the present disclosure will be described in detail with reference to accompanying drawings.

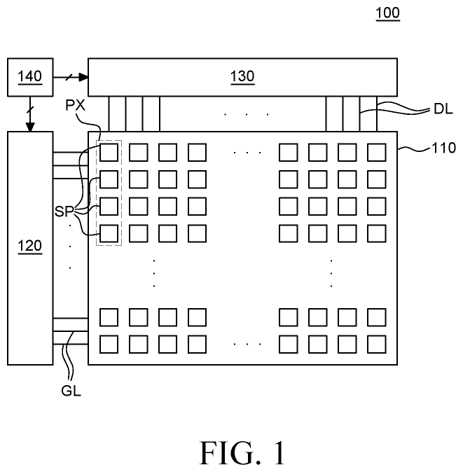

FIG. 1 is a block diagram illustrating a display device according to an embodiment of the present disclosure.

Referring to FIG. 1, a display device 100 according to an exemplary embodiment of the present disclosure includes a display panel 110, a gate driver 120, a data driver 130, and a timing controller 140.

The display panel 110 (or a pixel unit or a display unit) displays an image. The display panel 110 may include various circuits, signal lines, and light emitting diodes disposed on the substrate. The display panel 110 includes a plurality of pixels PX which is divided by a plurality of data lines DL and a plurality of gate lines GL intersecting each other and is connected to the plurality of data lines DL and the plurality of gate lines GL.

The display panel 110 includes a display area in which an image is displayed and a non-display area in which various signal lines or pads are formed. The non-display area is located at the outside of the active area. The display panel 110 may be implemented by a display panel used in various display devices such as a liquid crystal display device, an organic light emitting display device, or an electrophoretic display device. Hereinafter, it is described that the display panel 110 is a panel used in the organic light emitting display device, but the exemplary embodiment of the present disclosure is not limited thereto.

The display panel 110 includes a plurality of pixels PX disposed on the active area. Each of the plurality of pixels PX may be electrically connected to a corresponding gate line, among gate lines GL and a corresponding data line, among data lines DL. Therefore, a gate signal and a data signal are applied to each pixel PX, through the gate line and the data line. Each pixel may implement the gray scale by the applied gate signal and data signal and finally, the image may be displayed in the active area by the gray scales displayed by the pixels PX.

Further, each of the plurality of pixels PX includes a plurality of sub pixels SP. The sub pixels SP included in one pixel PX may emit different color light. For example, the sub pixels SP may include a red sub pixel, a green sub pixel, a blue sub pixel, and a white sub pixel, but are not limited thereto. The plurality of sub pixels SP may configure a pixel PX. That is, the red sub pixel, the green sub pixel, the blue sub pixel, and the white sub pixel configure one pixel PX and the display panel 110 may include a plurality of pixels PX.

The timing controller 140 (or a timing control circuit) receives timing signals such as a vertical synchronization signal, a horizontal synchronization signal, a data enable signal, or a dot clock by means of a receiving circuit such as an LVDS or TMDS interface connected to the outside (for example, a host system). The timing controller 140 generates and outputs timing control signals based on the input timing signal to control the data driver 130 and the gate driver 120.

The data driver 130 (or a data driving circuit) supplies a data signal to the plurality of sub pixels SP. To this end, the data driver 130 includes at least one source drive IC (integrated circuit). The source drive IC may be supplied with digital video data and a source timing control signal from the timing controller 140. The source drive IC converts digital video data into a gamma voltage in response to a source timing control signal to generate a data signal and supply the data signal to the sub pixels SP through the data lines DL of the display panel 110. The source drive IC may be connected to the data line DL of the display panel 110 by a chip on glass (COG) process or a tape automated bonding (TAB) process. Further, the source drive IC is formed on the display panel 110 or is formed on a separate PCB substrate to be connected to the display panel 110.

The gate driver 120 (or a gate driving circuit, a scan driver, or a scan driving circuit) supplies a gate signal to the plurality of sub pixels SP. The gate driver 120 may include a level shifter and a shift register. The level shifter shifts a level of a clock signal input at a transistor-transistor-logic (TTL) level from the timing controller 140 and then supplies the clock signal to the shift register. The shift register may be formed in the non-display area of the display panel 110, by a GIP manner, but is not limited thereto. The shift register is configured by a plurality of stages which shifts the gate signal to output, in response to the clock signal and the driving signal. The plurality of stages included in the shift register sequentially outputs the gate signal through a plurality of output terminals.

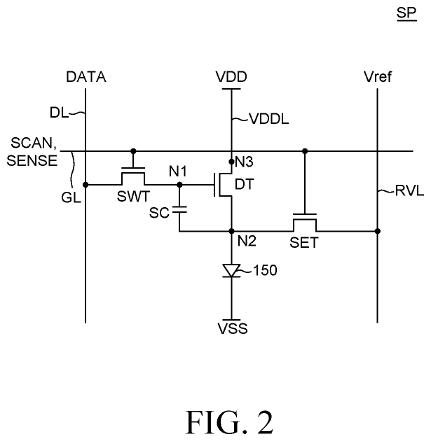

Hereinafter, a driving circuit (pixel circuit) for driving one sub pixel SP will be described in more detail with reference to FIG. 2.

FIG. 2 is a circuit diagram illustrating an example of a sub pixel included in a display device according to an exemplary embodiment.

In the meantime, in FIG. 2, a circuit diagram of one sub pixel, among the plurality of sub pixels SP included in the display device 100 which has been described with reference to FIG. 1.

Referring to FIG. 2, the sub pixel SP may include a switching transistor SWT, a sensing transistor SET, a driving transistor DT, a storage capacitor SC, and a light emitting diode 150.

The light emitting diode 150 may include an anode, an emission layer, and a cathode. For example, the emission layer may be an organic layer and the organic layer may include various organic layers such as a hole injection layer, a hole transport layer, an organic light emitting layer, an electron transport layer, and an electron injection layer. The anode of the light emitting diode 150 may be connected to a driving transistor DT (for example, an output terminal of a driving transistor DT) and a low potential voltage VSS may be applied to the cathode of the light emitting diode 150.

In the meantime, even though in FIG. 2, it is described that the light emitting diode 150 is an organic light emitting diode, the exemplary embodiment of the present disclosure is not limited thereto. For example, the light emitting diode 150 may be an inorganic light emitting diode (for example, an LED).

The driving transistor DT supplies a driving current to the light emitting diode 150 to allow the light emitting diode 150 to emit light. The driving transistor DT may include a gate electrode connected to a first node N1, a source electrode (or an output terminal) connected to a second node N2, and a drain electrode (or an input terminal) connected to a third node N3. The first node N1 to which the gate electrode of the driving transistor is connected is connected to the switching transistor SWT. The third node N3 to which the drain electrode is connected is connected to a high potential voltage line VDDL to be applied with a high potential voltage VDD. The second node N2 to which the source electrode is connected is connected to the anode of the light emitting diode 150.

The switching transistor SWT transmits the data signal DATA (or a data voltage) to the gate electrode of the driving transistor DT (or the first node N1). The switching transistor SWT may include a gate electrode connected to the gate line GL, a drain electrode connected to the data line DL, and a source electrode connected to the gate electrode of the driving transistor DT (or the first node N1). The switching transistor SWT is turned on by a scan signal SCAN (or a gate signal) supplied from the gate line GL to transmit a data voltage DATA (or a data voltage) supplied from the data line DL to the gate electrode of the driving transistor DT (or the first node N1).

The storage capacitor SC maintains a voltage (data voltage) corresponding to the data signal DATA for one frame. One electrode of the storage capacitor SC is connected to the first node N1 and the other electrode is connected to the second node N2. That is, the storage capacitor SC is connected between the gate electrode and the source electrode of the driving transistor DT.

In the meantime, as a driving time of each sub pixel SP is increased, the circuit element such as the driving transistor DT may be degraded. Accordingly, a unique characteristic value of the circuit element such as a driving transistor DT may be changed. Here, the unique characteristic value of the circuit element may include a threshold voltage Vth of the driving transistor DT or a mobility a of the driving transistor DT. The change in the characteristic value of the circuit element may cause a luminance change of the corresponding sub pixel SP. Accordingly, the change in the characteristic value of the circuit element may be used as the same concept as the luminance change of the sub pixel SP.

Further, the degree of the change in the characteristic values between circuit elements of each sub pixel SP may vary depending on a degree of degradation of each circuit element. Such a difference in the changing degree of the characteristic values between the circuit elements may cause a luminance deviation between the sub pixels SP. Accordingly, the characteristic value deviation between circuit elements may be used as the same concept as the luminance deviation between the sub pixels SP. The change in the characteristic values of the circuit elements, that is, the luminance change of the sub pixel SP and the characteristic value deviation between the circuit elements, that is, the luminance deviation between the sub pixels SP may cause problems such as the degradation of the accuracy for luminance expressiveness of the sub pixel SP or an erroneous screen.

Therefore, the display device 100 (see FIG. 1) according to the exemplary embodiment of the present disclosure provides a sensing function of sensing a characteristic value for the sub pixel SP and a compensating function of compensating for the characteristic value of the sub pixel SP using the sensing result.

For example, as illustrated in FIG. 2, the sub pixel SP further includes a sensing transistor SET for controlling a voltage state of a source electrode of the driving transistor DT.

The sensing transistor SET is connected between the source electrode of the driving transistor DT and a reference voltage line RVL which supplies a reference voltage Vref and includes a gate electrode which is connected to the gate line GL. Therefore, the sensing transistor SET is turned on by the sensing signal SENSE applied through the gate line GL to supply the reference voltage Vref which is supplied through the reference voltage line RVL to the source electrode of the driving transistor DT. Further, the sensing transistor SET may be utilized as one of voltage sensing paths for the source electrode of the driving transistor DT.

As described above, the reference voltage Vref is applied to the source electrode of the driving transistor DT by means of the sensing transistor SET which is turned on by the sensing signal SENSE. Further, a voltage for sensing the threshold voltage Vth of the driving transistor DT or the mobility a of the driving transistor DT is detected by the reference voltage line RVL. Further, the data driver 130 (see FIG. 1) of the display device 100 (see FIG. 1) may compensate for the data voltage DATA in accordance with a variation of the threshold voltage Vth of the driving transistor DT or the mobility a of the driving transistor DT.

In the meantime, as illustrated in FIG. 2, the switching transistor SWT and the sensing transistor SET included in the sub pixel SP may share one gate line GL. That is, the switching transistor SWT and the sensing transistor SET are connected to the same gate line GL to be supplied with the same signal (gate signal). However, for the convenience of description, in the above description, a signal which is applied to the gate electrode of the switching transistor SWT is referred to as a scan signal SCAN and a signal which is applied to the gate electrode of the sensing transistor SET is referred to as a sensing signal SENSE. However, the scan signal SCAN and the sensing signal SENSE applied to one sub pixel SP are the same signal which is transmitted through the same gate line GL.

However, this is just illustrative so that the exemplary embodiment of the present disclosure is not limited thereto. For example, only the switching transistor SWT is connected to the gate line GL and the sensing transistor SET may be connected to a separate sensing line. Therefore, the scan signal SCAN is applied to the switching transistor SWT through the gate line GL and the sensing signal SENSE is applied to the sensing transistor SET through the sensing line.

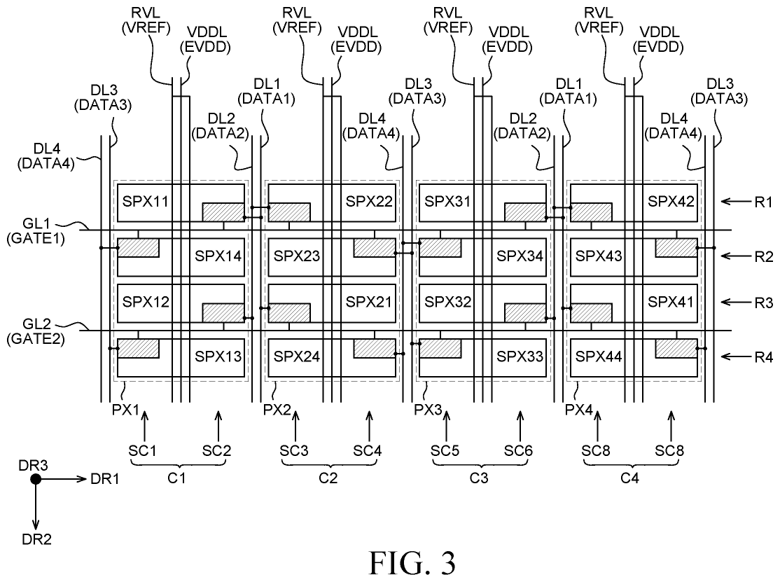

Hereinafter, as illustrated in FIG. 2, it will be described that the switching transistor SWT and the sensing transistor SET included in the sub pixel SP share one gate line GL. Therefore, hereinafter, the scan signal SCAN and the sensing signal SENSE are defined as gate signals GATE1, GATE2, GATE3, and GATE4 and a placement relationship of the plurality sub pixels will be described with reference to FIGS. 3 to 7.

FIG. 3 is a block diagram for explaining one example of a placement relationship of sub pixels included in a display device according to an exemplary embodiment.

In FIG. 3, for the convenience of description, four pixels which are disposed in a 1×4 matrix are illustrated. The placement relationship in the form of a 1×4 matrix illustrated in FIG. 3 can be understood as a result of repeating the placement relationship of two pixels disposed in a 1×2 matrix. Therefore, on the active area of the display device 100 (see FIG. 1) of the present disclosure, the placement relationship of two pixels disposed in a 1×2 matrix may be at least partially repeated.

For the convenience of description, a horizontal direction on the plane is referred to as a first direction (or a row direction) and a vertical direction on the plane is referred to as a second direction (or a column direction). In one embodiment, the first direction and the second direction are different from each other such as perpendicular to each other. Further, a direction (or a thickness direction) which is perpendicular to a plane defined by the first direction and the second direction is mentioned as a third direction.

Referring to FIG. 3, pixels PX1, PX2, PX3, and PX4 are disposed to be spaced apart from each other. Further, one pixel includes four sub pixels. For example, one pixel includes first sub pixels SPX11, SPX21, SPX31, SP41, second sub pixels SPX12, SPX22, SPX32, SPX42, third sub pixels SPX13, SPX23, SPX33, and SPX43, and fourth sub pixels SPX14, SPX24, SPX34, and SPX44. The first sub pixel SPX11, SPX21, SPX31, and SPX41 are red sub pixels, the second sub pixels SPX12, SPX22, SPX32, SPX42 are blue sub pixels, the third sub pixels SPX13, SPX23, SPX33, SPX43 are green sub pixels, and the fourth sub pixels SPX14, SPX24, SPX34, SPX44 are white sub pixels. However, various exemplary embodiments of the present disclosure are not limited thereto and sub pixels may be changed into a sub pixel representing various colors (Magenta, Yellow, and Cyan).

The first pixel PX1 is disposed in a first column C1 (for example, a 2i−1-th column, i is an integer of 0 or larger). The second pixel PX2 is disposed in a second column C2, the third pixel PX3 is disposed in a third column C3, and the fourth pixel PX4 is disposed in a fourth column C4.

Pixels disposed in the first column C1 (for example, a 2i−1-th column when i is 1) and the third column C3 (a 2i−1-th column when i is 2) may include sub pixels which are disposed in the substantially same manner. Pixels disposed in the second column C2 (for example, a 2i-th column when i is 2) and the fourth column C4 (a 2i-th column when i is 2) may include sub pixels which are disposed in the substantially same manner.

One or two or more data lines may be disposed between a k-th column (k is a natural number) and a k+1-th column. For example, first and second data lines DL1 and DL2 are disposed between the first column C1 and the second column C2. For example, third and fourth data lines DL3 and DL4 are disposed between the second column C2 and the third column C3. For example, first and second data lines DL1 and DL2 are disposed between the third column C3 and the fourth column C4.

Further, in each row, sub pixels are disposed. For example, in a first row R1, first sub pixels SPX11 and SPX31 of the first and third pixels PX1 and PX3 are disposed along the first direction DR1 and second sub pixels SPX22 and SPX42 of the second and fourth pixels PX2 and PX4 are disposed along the first direction DR1. For example, in a second row R2, fourth sub pixels SPX14 and SPX34 of the first and third pixels PX1 and PX3 are disposed along the first direction DR1 and third sub pixels SPX23 and SPX43 of the second and fourth pixels PX2 and PX4 are disposed along the first direction DR1. For example, in a third row R3, second sub pixels SPX12 and SPX32 of the first and third pixels PX1 and PX3 are disposed along the first direction DR1 and first sub pixels SPX21 and SPX41 of the second and fourth pixels PX2 and PX4 are disposed along the first direction DR1. For example, in a fourth row R4, third sub pixels SPX13 and SPX33 of the first and third pixels PX1 and PX3 are disposed along the first direction DR1 and fourth sub pixels SPX24 and SPX44 of the second and fourth pixels PX2 and PX4 are disposed along the first direction DR1.

One column may include two or more sub columns. For example, the first column C1 may include a first sub column SC1 and a second sub column SC2. For example, the second column C2 may include a third sub column SC3 and a fourth sub column SC4. For example, the third column C3 may include a fifth sub column SC5 and a sixth sub column SC6. That is, a k-th column may include a 2k−1-th sub column and a 2k-th sub column.

One or more wiring lines (for example, a high potential voltage line VDDL and a reference voltage line RVL) may be disposed between a 2k−1-th sub column and a 2k-th sub column. For example, the reference voltage line RVL may be disposed between the 2k−1-th sub column and the 2k-th sub column. For example, the high potential voltage line VDDL may be disposed between the 2k−1-th sub column and the 2k-th sub column. For example, the reference voltage line RVL and the high potential voltage line VDDL may be disposed between the 2k−1-th sub column and the 2k-th sub column. For example, two reference voltage lines RVL and the high potential voltage line VDDL may be disposed between the 2k−1-th sub column and the 2k-th sub column. For example, when two reference voltage lines RVL and the high potential voltage line VDDL are disposed between the 2k−1-th sub column and the 2k-th sub column, the high potential voltage line VDDL may be disposed between the two reference voltage lines RVL. Further, two reference voltage lines RVL are configured as a single line in a lead-in unit (for example, one wiring line in a top lead-in unit of the display panel) of the display panel and the single line is separated in a pixel crossing portion to be configured as two wiring lines. The two wiring lines are connected to the one wiring line.

One or more wiring lines (for example, data line(s) DL1, DL2, DL3, and DL4) may be disposed between the 2k-th sub column and a 2k+1-th sub column. For example, two or more of first to fourth data lines DL1, DL2, DL3, and DL4 may be disposed between the 2k-th sub column and the 2k+1-th sub column. For example, first and second data lines DL1 and DL2 may be disposed between the 2k-th sub column and the 2k+1-th sub column. For example, third and fourth data lines DL3 and DL4 may be disposed between the 2k-th sub column and the 2k+1-th sub column. As described above, a first pair configured by the first and second data lines DL1 and DL2 and a second pair configured by the third and fourth data lines DL3 and DL4 are alternately disposed between the 2k-th sub column and the 2k+1-th sub column.

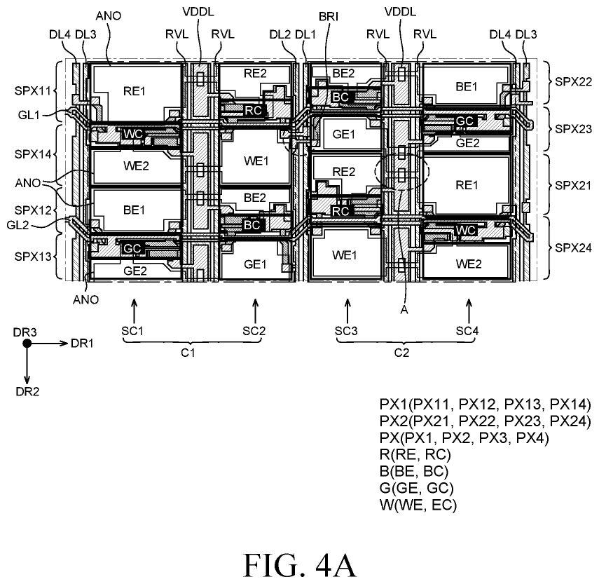

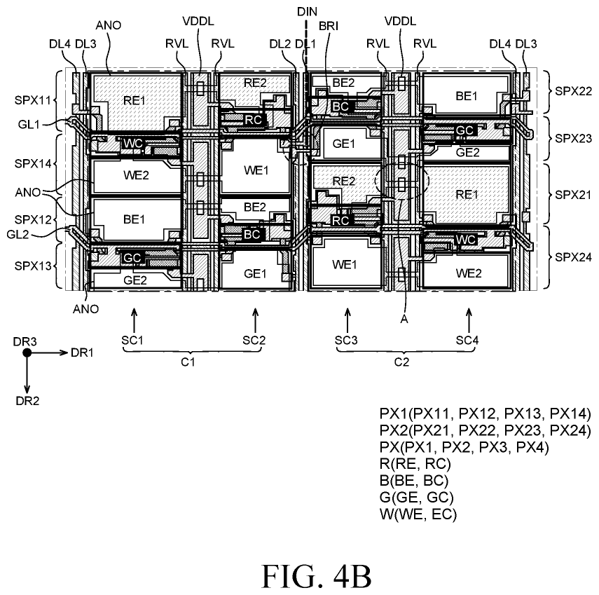

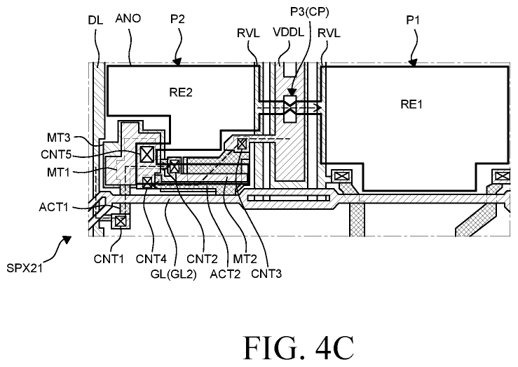

In one exemplary embodiment, the voltage line (for example, the reference voltage line RVL and/or the high potential voltage line VDDL) may be disposed so as to cross the sub pixel. However, it is not limited thereto and the voltage line may be disposed to perpendicularly pass through a major axis of the sub pixel. Hereinafter, it will be described below with reference to FIG. 4 and the sub pixel may be divided into two emission areas by a voltage line.

FIG. 4A is a layout for explaining one example of a placement relationship of sub pixels included in a display device according to an exemplary embodiment.

FIG. 4B is a referential view for explaining an example of an output of a first sub pixel of a display device according to an exemplary embodiment.

FIG. 4C is a view illustrating an example that a display device according to an exemplary embodiment transmits a data signal to sub pixel(s).

FIGS. 4A and 4B illustrate an example of the placement relationship which has been described with reference to FIG. 3, in detail with the layout. In the following description, a description for a configuration which is substantially same as that described with reference to FIG. 3 will be omitted or contracted. Further, in FIGS. 4A and 4B, for the convenience of description, only two pixels which are disposed in a 1×2 matrix are illustrated. Further, a unit pixel is illustrated only by four sub pixels which are disposed in a 4×1 matrix. On the active area of the display device of the present disclosure, two pixels disposed in a 1×2 matrix are repeatedly disposed.

Each of the first to fourth sub pixels may have a circuit configuration which is the substantially same as the circuit of the sub pixel which has been described with reference to FIG. 2. For example, each of the circuit elements of the sub pixels illustrated in FIGS. 4A to 4C includes the switching transistor, the sensing transistor, the driving transistor, and the storage capacitor of the sub pixel which has been described with reference to FIG. 2. Each of the light emitting diodes of the sub pixels may be the substantially same as or similar to the light emitting diode which has been described with reference to FIG. 2.

For the convenience of description, a horizontal direction on the plane is referred to as a first direction (or a row direction) and a vertical direction (or a perpendicular direction) on the plane is referred to as a second direction (or a column direction). Further, a direction (or a thickness direction) which is perpendicular to a plane defined by the first direction and the second direction is mentioned as a third direction.

Referring to FIG. 4A, on the active area, a first pixel PX1 in which the sub pixels are disposed in a first manner (e.g., a first arrangement) and a second pixel PX2 in which in which the sub pixels are disposed in a second manner (e.g., a second arrangement) are included. The first sub pixel PX1 disposed in the first manner may have a structure in which the first sub pixel SPX11, the fourth sub pixel SPX14, the second sub pixel SPX12, and the third sub pixel SPX13 are sequentially disposed along the second direction. The second pixel PX2 disposed in the second manner may have a structure in which the second sub pixel SPX22, the third sub pixel SPX23, the first sub pixel SPX21, and the fourth sub pixel SPX24 are sequentially disposed. The first pixel PX1 and the second pixel PX2 are one pixel group and are repeatedly formed on the entire active area.

The sub pixel includes one or two or more light emitting diodes. For example, each of the first to fourth sub pixels may include first to fourth light emitting diodes.

In one exemplary embodiment, each light emitting diode may include a large-area light emitting diode and a small-area light emitting diode. For example, the first light emitting diode may include a first large-area light emitting diode RE1 and a first small-area light emitting diode RE2. For example, the second light emitting diode may include a second large-area light emitting diode BE1 and a second small-area light emitting diode BE2. The third light emitting diode may include a third large-area light emitting diode GE1 and a third small-area light emitting diode GE2. The fourth light emitting diode may include a fourth large-area light emitting diode WE1 and a fourth small-area light emitting diode WE2.

The large-area light emitting diodes (for example, the first to fourth large-area light emitting diodes RE1, BE1, GE1, and WE1 and the small-area light emitting diodes (for example, the first to fourth small-area light emitting diodes RE2, BE2, GE2, and WE2) are electrically connected to an integrally formed anode electrode ANO. However, the first emission area by the large-area light emitting diode and the second emission area by the small-area light emitting diode are spatially divided by a bank layer (not illustrated). For example, the first large-area light emitting diode RE1 and the first small-area light emitting diode RE2 are connected by the integrally formed anode electrode ANO, and are divided into a first emission area and a second emission area by the bank layer. For example, the second large-area light emitting diode BE1 and the second small-area light emitting diode BE2 are connected by the integrally formed anode electrode ANO, and are divided into a first emission area and a second emission area by the bank layer. For example, the third large-area light emitting diode GE1 and the third small-area light emitting diode GE2 are connected by the integrally formed anode electrode ANO, and are divided into a first emission area and a second emission area by the bank layer. For example, the fourth large-area light emitting diode WE1 and the fourth small-area light emitting diode WE2 are connected by the integrally formed anode electrode ANO, and are divided into a first emission area and a second emission area by the bank layer. Hereinafter, the anode electrode AND is formed of a transparent electrode (for example, an ITO electrode), but various exemplary embodiments of the present disclosure are not limited thereto.

Each of the large-area light emitting diodes RE1, BE1, GE1, and WE1 corresponds to the first emission area and each of the small-area light emitting diodes RE2, BE2, GE2, and WE2 corresponds to the second emission area. The large-area light emitting diode may be formed to be larger than the small-area light emitting diode.

The light emitting diodes which configure the first to fourth sub pixels SPX11, . . . , SPX24 may be supplied with currents from the first to fourth circuit elements RC, BC, GC, and WC. To this end, the first to fourth sub pixels SPX11, . . . , SPX24 may include the first to fourth circuit elements RC, BC, GC, and WC to supply the currents to the light emitting diodes. For example, the first large-area and small-area light emitting diodes RE1 and RE2 are supplied with the current from the first circuit element RC. For example, the second large-area and small-area light emitting diodes BE1 and BE2 are supplied with the current from the second circuit element BC. For example, the third large-area and small-area light emitting diodes GE1 and GE2 are supplied with the current from the third circuit element GC. For example, the fourth large-area and small-area light emitting diodes WE1 and WE2 are supplied with the current from the fourth circuit element WC.

The data lines DL1, DL2, DL3, and DL4 include a first data line DL1 connected to the first sub pixels SPX11 and SPX21 and a second data line DL2 connected to the second sub pixels SPX12 and SPX22. Further, the data lines include a third data line DL3 connected to the third sub pixels SPX13 and SPX23 and a fourth data line DL4 connected to the fourth sub pixels SPX14 and SPX24. The first data line DL1 and the second data line DL2 are disposed to be adjacent to each other. The third data line DL3 and the fourth data line DL4 are disposed to be adjacent to each other. The first data line DL1 and the second data line DL2 may be disposed to be spatially separated from the third data line DL3 and the fourth data line DL4 with a pixel therebetween. Data lines may extend along the second direction DR2.

At least some of the data lines is disposed on one side of the pixel and the others are disposed on the other side of the pixel. For example, the first and second data lines DL1 and DL2 are disposed on one side of the pixel and the third and fourth data lines DL3 and DL4 are disposed on the other side of the pixel. For example, with respect to the second column, the first and second data lines DL1 and DL2 are disposed on a left side of the second pixel PX2 and the third and fourth data lines DL3 and DL4 are disposed on the right side of the second pixel PX2.

In one exemplary embodiment, the data lines are disposed between the pixel elements. Specifically, at least some of data lines may be disposed between two or more circuit elements. For example, at least some of the first and second data lines DL1 and DL2 may be disposed between the first circuit element RC of the first pixel PX1 and the second circuit element BC of the second pixel PX2. For example, at least some of the third and fourth data lines DL3 and DL4 may be disposed between the third circuit element GC of the second pixel PX2 and the fourth circuit element WC and the circuit elements of a third pixel (not shown).

In one exemplary embodiment, the first and second data lines DL1 and DL2 which are located at one edge in the first direction DR1 may not be disposed between the circuit elements. The third and fourth data lines DL3 and DL4 which are located at the other edge in the first direction DR1 may not be disposed between the circuit elements.

For example, the first and second data lines DL1 and DL2 may be disposed between the first and second circuit elements RC and BC. The first data line DL1 supplies a data signal to the first circuit element RC and the second data line DL2 supplies a data signal to the second circuit element BC. That is, each of the first and second data lines DL1 and DL2 may be disposed between the circuit elements (that is, the first and second circuit elements RC and BC) which supply data signals.

For example, the third and fourth data lines DL3 and DL4 may be disposed between the third and fourth circuit elements GC and WC. The third data line DL3 supplies a data signal to the third circuit element GC and the fourth data line DL4 supplies a data signal to the fourth circuit element WC. That is, each of the third and fourth data lines DL3 and DL4 may be disposed between the circuit elements (that is, the third and fourth circuit elements GC and WC) which supply data signals.

In the meantime, circuit elements provided in the 2k-th sub column and circuit elements provided in the 2k+1-th sub column may be disposed to be opposite to each other with the data line therebetween. For example, the first and second circuit elements RC and BC provided in the second sub column SC2 may be disposed to be opposite to the third and fourth circuit elements GC and WC provided in the third sub column with the first and second data lines DL1 and DL2 therebetween. Further, for example, the third and fourth circuit elements GC and WC provided in the fourth sub column SC4 may be disposed to be opposite to the first and second circuit elements RC and BC provided in the fifth sub column (not illustrated) with the third and fourth data lines DL3 and DL4 therebetween.

Further, in one exemplary embodiment, the first pixel PX1 disposed on one side of the first and second data lines DL1 and DL2 and the second pixel disposed on the other side may have an asymmetrical structure. For example, the first pixel PX1 and the second pixel PX2 may have an asymmetric structure with respect to the first and second data lines DL1 and DL2. Alternatively, the first sub pixels SPX11 and SPX21 and the fourth sub pixels SPX14 and SPX24 may configure a first sub pixel group and the second sub pixels SPX12 and SPX22 and the third sub pixels SPX13 and SPX33 may configure a second sub pixel group. In the case of the first pixel PX1 located on the left side of the first and second data lines DL1 and DL2, the first sub pixel group and the second sub pixel group are sequentially disposed with respect to the second direction DR2. In the case of the second pixel PX2 located on the right side of the first and second data lines DL1 and DL2, the second sub pixel group and the first sub pixel group are sequentially disposed with respect to the second direction DR2. However, it is not limited thereto and the first sub pixel group may be formed to have an area larger than the second sub pixel group.

Referring to FIGS. 4A and 4B, in one exemplary embodiment, the data signal DIN supplied through at least some of the first data lines DL1 may be transmitted to the first circuit board RC across the second data line DL2. Further, the data signal which is supplied through the other part of the first data lines DL1 may be transmitted to the first circuit element RC regardless of the second data line DL2. For example, in the relationship with the pixel is located on the left side of the first data line DL1, the first data line DL1 supplies the data signal to the first circuit element RC through the bridge BRI that is across the second data line DL2 in the plan view of the display device. The first data line DL1 which is common in the relationship with the pixel located on the right side supplies the data signal to the first circuit element RC located at the opposite direction (for example, a right side) to the second data line DL2 without the need for the bridge BRI.

In one exemplary embodiment, the data signal which is supplied through at least some of the second data lines DL2 may be transmitted to the second circuit element BC across the first data line DL1. Further, the data signal which is supplied through the other part of the second data lines DL2 may be transmitted to the second circuit element BC regardless of the first data line DL1. For example, in the relationship with the pixel located on the right side, the second data line DL2 supplies the data signal to the second circuit element BC through the bridge BRI across the first data line DL1. The second data line DL2 which is common in the relationship with the pixel located on the left side supplies the data signal to the second circuit element BC located at the opposite direction (for example, a left side) to the first data line DL1.

In one exemplary embodiment, the data signal which is supplied through at least some of the third data lines DL3 may be transmitted to the third circuit element GC across the fourth data line DL4. Further, the data signal which is supplied through the other part of the third data lines DL3 may be transmitted to the third circuit element GC regardless of the fourth data line DL4. For example, in the relationship with the pixel located on the left side, the third data line DL3 supplies the data signal to the third circuit element GC through the bridge BRI across the fourth data line DL4. The third data line DL3 which is common in the relationship with the pixel located on the right side supplies the data signal to the third circuit element GC located in the opposite direction (for example, a right side) to the fourth data line DL4.

In one exemplary embodiment, the data signal which is supplied through at least some of the fourth data lines DL4 may be transmitted to the fourth circuit element WC across the third data line DL3. Further, the data signal which is supplied through the other part of the fourth data lines DL4 may be transmitted to the fourth circuit element WC regardless of the third data line DL3. For example, in the relationship with the pixel located on the right side, the fourth data line DL4 supplies the data signal to the fourth circuit element WC through the bridge BRI across the third data line DL3. The fourth data line DL4 which is common in the relationship with the pixel located on the left side supplies the data signal to the fourth circuit element WC located in the opposite direction (for example, a left side) to the third data line DL3.

In one exemplary embodiment, the high potential voltage line VDDL, two reference voltage lines RVL, and two gate lines GL1 and GL2 pass through one pixel. At this time, the gate lines extend in the first direction DR1 and the high potential voltage line VDDL and the reference voltage lines RVL extend along the second direction DR2. Therefore, the gate lines GL1 and GL2 and the remaining voltage lines (for example, the high potential voltage line VDDL and the reference voltage lines RVL) vertically intersect. In one exemplary embodiment, two gate lines GL1 and GL2 pass through one pixel and at this time, the intersections of two gate lines GL1 and GL2 and the high potential voltage line VDDL are defined as a first point and a second point and the first point may be disposed above the second point.

In one exemplary embodiment, the gate lines GL1 and GL2 may include a first gate line GL1 and a second gate line GL2. The first gate line GL1 is disposed between the first and fourth sub pixels SPX11 and SPX14 of the first sub pixel group (with respect to the first pixel PX1) and is disposed between the second and third sub pixels SPX22 and SPX23 of the second sub pixel group (with respect to the second pixel PX2). Further, the second gate line GL2 is disposed between the second and third sub pixels SPX12 and SPX13 of the second sub pixel group (with respect to the first pixel PX1) and is disposed between the first and fourth sub pixels SPX21 and SPX24 of the first sub pixel group (with respect to the second pixel PX2). At this time, the first gate line GL1 disposed between the first and fourth sub pixels and the second gate line GL2 disposed between the second and third sub pixels may be parallel to each other. For example, the first gate line GL1 and the second gate line GL2 may be disposed to be parallel to each other along a minor axis direction of the sub pixel and the minor axis direction of the sub pixel may correspond to the second direction DR2.

Further, as described above, the gate lines GL1 and GL2 may intersect the high potential voltage line VDDL at two or more points (for example, the first point and the second point). In one exemplary embodiment, the first circuit element RC and the fourth circuit element WC may be disposed to be opposite to each other with respect to the first point. That is, the first point is between the first circuit element and the fourth circuit element in the plan view. In one exemplary embodiment, the second circuit element BC and the fourth circuit element GC may be disposed to be opposite to each other with respect to the second point. That is, the second point is between the second circuit element and the third circuit element in the plan view. For example, the first circuit element RC and the fourth circuit element WC are disposed in a diagonal direction with respect to the first point and the second circuit element BC and the third circuit element GC are also disposed in a diagonal direction with respect to the second point.

In the meantime, in one exemplary embodiment, the gate lines GL1 and GL2 may be divided into two or more sub gate lines (e.g., two or more wiring lines) in a first section where the gate lines intersect the other wiring lines (for example, the high potential voltage line VDD, the reference voltage line RVL, and the data lines). Further, the gate lines GL1 and GL2 may be disposed as one wiring line in a second section which the gate lines are non-intersecting (e.g., do not intersect) with the other wiring lines.

In one exemplary embodiment, when the gate lines GL1 and GL2 are divided into two or more sub gate lines, the gate lines GL1 and GL2 may intersect the other wiring lines (for example, the high potential voltage line VDD, the reference voltage line RVL, and the data lines) in at least four points with respect to one pixel. At this time, the first circuit element RC and the fourth circuit element WC may be disposed to be opposite to each other with respect to a first intersection and a second intersection which are sequentially located along the second direction DR2. Further, the second circuit element BC and the third circuit element GC may be disposed to be opposite to each other with respect to a third intersection and a fourth intersection which are sequentially located along the second direction DR2.

Further, the gate lines GL1 and GL2 may intersect the data lines DL1 and DL1 while forming an acute angle in one or two or more points. For example, the gate lines GL1 and GL2 include a first gate line GL1 and a second gate line GL2 and the second gate line is defined to be lower than the first gate line GL1 along the second direction DR2.

In one exemplary embodiment, the first gate line GL1 is disposed so as to pass between the first sub pixel group of the first pixel PX1 and the second sub pixel group of the second pixel PX2. The second gate line GL2 is disposed so as to pass between the second sub pixel group of the first pixel PX1 and the first sub pixel group of the second pixel PX2.

In one exemplary embodiment, the first gate line GL1 and the second gate line GL2 are formed to extend along the first direction DR1 so as to be parallel to each other along the first direction DR2.

In the meantime, in on exemplary embodiment, the gate lines GL1 and GL2 in the first pixel PX1 and the gate lines GL1 and GL2 in the second pixel PX2 may be electrically connected while forming a predetermined inclination angle. For example, the first gate line GL1 which passes through the first sub pixel group in the first pixel PX1 passes through the second sub pixel group in the second pixel PX2 and forms a predetermined inclination angle with respect to the first direction DR1 which is not parallel to the first direction DR1 between the first pixel PX1 and the second pixel PX2. Further, for example, the second gate line GL2 which passes through the second sub pixel group in the first pixel PX1 passes through the first sub pixel group in the second pixel PX2 and forms a predetermined inclination angle which is not parallel to the first direction DR1 between the first pixel PX1 and the second pixel PX2. Here, the inclination angle formed by the first gate line GL1 and the inclination angle formed by the second gate line GL2 may have the same angle. As described above, due to the inclination angle formed by the gate lines (for example, the first and second gate lines GL1 and GL2 between the pixels, the gate line and the data lines (for example, the first to fourth data lines DL1, . . . , DL2) intersect while forming the acute angle.

Even though it is not limited thereto, according to various exemplary embodiments, the gate lines GL1 and GL2 may be divided into two wiring lines in the intersection with the data lines DL1, . . . , DL4. Therefore, in the intersection of the data line and the gate line, gate line which transmits a specific gate signal may intersect the data lines in two points.

In one exemplary embodiment, when the gate lines GL1 and GL2 are divided into two or more sub gate lines, the gate lines GL1 and GL2 may intersect the data lines DL1, DL2, DL3, and DL4 in at least four points with respect to one pixel.

In one exemplary embodiment, the voltage lines (for example, the reference voltage line RVL and the high potential voltage line VDDL) may be disposed between the circuit elements RC, BC, GC, and WC. Specifically, at least some of data lines may be disposed between two or more circuit elements. For example, the voltage line may be disposed between the first and fourth circuit elements RC and WC. For example, the voltage line may be disposed between the first and third circuit elements RC and GC. For example, the voltage line may be disposed between the second and third circuit elements BC and GC. For example, the voltage line may be disposed between the second and fourth circuit elements BC and WC.

In one exemplary embodiment, the high potential voltage line VDD may be disposed two strands of the reference voltage lines. Therefore, two reference voltage lines RVL and one high potential voltage line VDDL may be disposed between the circuit elements.

Hereinafter, a connection relationship of a pixel for driving each pixel will be described with reference to FIG. 4C. In FIG. 4C, a first sub pixel PX21 of a second pixel PX2 is enlarged and the connection relationship may be employed substantially the same for the remaining sub pixels.

Referring to FIG. 4C, a data line DL, a gate line GL, a first semiconductor layer ACT1, and a second metal MT2 may configure a switching transistor. The data line DL and the second metal MT2 serve as a 1-1-th source-drain electrode and a 1-2-th source-drain electrode, respectively and the gate line GL serves as a gate electrode. When a gate-on voltage is applied to the gate line GL, a data voltage which is supplied through the data line DL is transmitted to the second metal MT2. To this end, the 1-1-th source-drain electrode and a first semiconductor layer ACT1 are electrically connected through a first contact CNT1 and the 1-2-th source-drain electrode and a second semiconductor layer ACT2 are electrically connected through a second contact CNT2.

The high potential voltage line VDDL, the second semiconductor layer ACT2, the first metal MT1, and the second metal MT2 may configure the driving transistor. The high potential voltage line VDDL and the first metal MT1 serve as a 2-1-th source-drain electrode and a 2-2-th source-drain electrode, respectively, and the second metal MT2 serves as a gate electrode. The second metal MT2 form a storage capacitor with a third metal MT3 disposed below the second semiconductor layer ACT2 and the storage capacitor stores a data voltage supplied from the data line DL. The driving transistor is turned on by a data voltage stored in the storage capacitor and an amount of current supplied from the 2-1-th source-drain electrode to the 2-2-th source-drain electrode may be adjusted. To this end, the 2-1-th source-drain electrode is electrically connected to a second semiconductor layer ACT2 through a third contact CNT3 and the 3-2-th source-drain electrode is electrically connected to the second semiconductor layer ACT2 through a fourth contact CNT4.

The anode is disposed above the first metal MT1 and the anode and the first metal MT1 are electrically connected through a fifth contact CNT5. The first metal MT1 may supply a driving current for driving the large-area light emitting diode RE1 and the small-area light emitting diode RE2 to the anode ANO.

However, it is not limited thereto and the first semiconductor layer ACT1 and the second semiconductor layer ACT2 may be configured by the substantially same material.

Referring to FIG. 4C again, as described above, the sub pixel may include various light emitting diodes. For example, the first sub pixel includes large-area light emitting diodes RE1, BE2, GE1, and WE1 and small-area light emitting diodes RE2, BE2, GE2, and WE2. The large-area light emitting diodes RE1, BE2, GE1, and WE1 correspond to a first emission area and the small-area light emitting diodes RE2, BE2, GE2, and WE2 correspond to a second emission area. The second emission area is smaller than the corresponding first emission area for each light emitting diode.

Referring to FIGS. 4A to 4C, in one exemplary embodiment, the anode electrode ANO (or an anode electrode or a pixel electrode) which configures the sub pixel may be formed to cover both the first emission area and the second emission area.

In a part A of FIGS. 4A and 4B, a third part P3 which connects a first part P1 and a second part P2 of the anode may be formed. Hereinafter, the anode ANO including the first part P1, the second part P2, and the third part P3 which connects the first part P1 and the second part P2 will be described with reference to FIGS. 4A to 4C.

In one exemplary embodiment, the anode ANO includes the first part P1 corresponding to the first emission area, the second part P2 corresponding to the second emission area, and the third part P3 which connects the first part P1 and the second part P2. Here, the first part P1 and the second part P2 are provided for driving operations of the large-area light emitting diodes RE1, BE1, GE1, and WE1 and the small-area light emitting diodes RE2, BE2, GE2, and WE2, respectively, and are disposed so as to correspond to individual emission areas. The third part P3 is disposed as a bridge for connecting the first part P1 and the second part P2.

In one exemplary embodiment, the third part P3 connects the first part P1 and the second part P2 across the high potential voltage line VDDL. That is, the third part P3 overlaps the high potential voltage line VDDL in a plan view of the display device. The third part P3 is not electrically connected to the high potential voltage line VDDL, but may be disposed to be spaced apart therefrom along a third direction in the plan view of the display device. The third P3 is a bridge for connecting the first and second parts P1 and P2 so that the third part P3 may be formed to have a smaller width than that of the first and second parts P1 and P2.

Referring to FIG. 4C again, a structure in which the first and second parts P1 and P2 are connected by the third part P3 is employed so that in various exemplary embodiments of the present disclosure, the third part P3 is disconnected/broken to shut off the power which is supplied to the first part P1. For example, with reference to the configuration of the first sub pixels SPX11 and SPX21, the large-area light emitting diode RE1 and the small-area light emitting diode RE2 are supplied with the power from the circuit element (for example, RC). Specifically, the large-area light emitting diode RE1 shares the electrode and the power source with the anode ANO of the first part P1 which is connected through the third part P3. When the third part P3 is disconnected, the first part P1 is not supplied with the power so that the sub pixel may emit light only through the small-area light emitting diode RE2. As described above, the third part P3 which is configured to be disconnectable may contribute to suppressing the complete darkening of the sub pixel. For example, when it is assumed that a short-circuit is generated between the anode ANO and the cathode (not illustrated) of the light emitting diode due to the foreign material, if the cause of the short-circuit is located in the first emission area, the third part P3 is disconnected to suppress the entire darkening of the sub pixel. According to this function, the third part may be referred to as a cutting part CP.

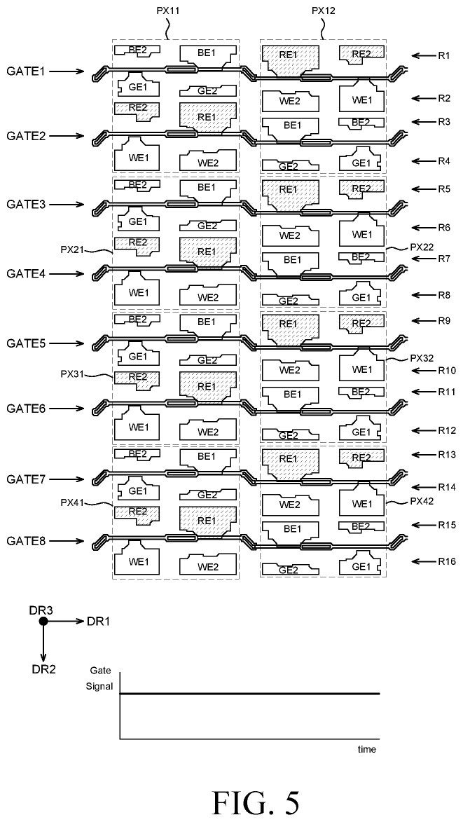

FIG. 5 is a view for explaining an example that a display device according to an exemplary embodiment drives a solid screen.

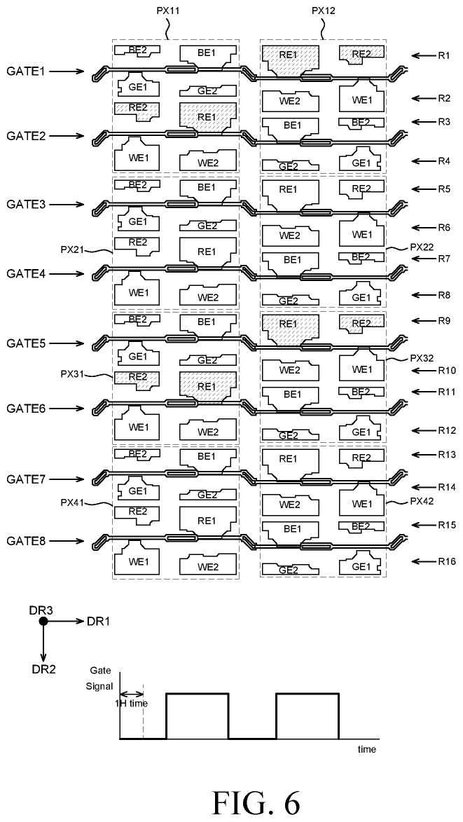

FIGS. 6 to 8 are views for explaining examples that a display device drives a horizontal one-by-one driving screen, a vertical one-by-one driving screen, and a dot driving screen.

In a display circuit structure of the related art, in order to implement a large-size OLED display, data lines of two adjacent pixels were bundled. For example, a first data line for the first pixel and a second data line for a second pixel adjacent to the first pixel were bundled or coupled as one wiring line. By doing this, in order to drive a solid screen, a toggle of the data signal is suppressed. According to various exemplary embodiments of the present disclosure, it is understood that a structure in which two or more data signals are bundled is not employed, through the above description. Moreover, according to various exemplary embodiments of the present disclosure, a data toggle when the solid screen is driven is not generated. This will be described below with reference to FIG. 5.

The solid screen is driven when the entire screen is driven with DC. When the display is driven, sub pixels which are disposed along one gate line are driven for one horizontal line time (horizontal time, 1H time) and sub pixels which are disposed along the other gate line are driven for a next horizontal line time. That is, the horizontal line time (1H time) is referred to as a period when a scan signal (or gate signal) GATE1, . . . , GATE4 is supplied through one gate line and 1H time may be sequentially supplied along gate lines. In the case of horizontal one-by-one driving, vertical one-by-one driving, and dot driving, a high level signal and a low level signal are alternately represented in accordance with one or two or more 1H times. The DC driving to express the solid screen may be configured only by a high level signal as a whole. That is, the same level of signal is supplied to all the gate lines.

According to various exemplary embodiments of the present disclosure, light emitting diodes RE1 and RE2 which represent red are disposed in a zigzag shape. That is, in the case of the first pixel PX11 and the second pixel PX12, the light emitting diodes RE1 and RE2 are located in a first row and a third row, respectively. In the case of the third pixel PX21 and the fourth pixel PX22, the light emitting diodes RE1 and RE2 are located in a fifth row and a seventh row, respectively. In the case of the fifth pixel PX31 and the sixth pixel PX32, the light emitting diodes RE1 and RE2 are located in a ninth row and an eleventh row, respectively. In the case of the seventh pixel PX41 and the eighth pixel PX42, the light emitting diodes RE1 and RE2 are located in a thirteenth row and a fifteenth row, respectively.

As described above, the light emitting diodes RE1 and RE2 are repeatedly disposed by changing columns every two rows. As a result, the light emitting diodes RE1 and RE2 are disposed in the entire display panel in a zigzag shape and this is the same for the light emitting diodes WE, GE, and BE which represent the other colors.

Consequently, according to various exemplary embodiments, when a DC signal is applied along the gate lines to drive the solid screen, the solid screen in which the light emitting diodes are driven in a zigzag pattern with respect to one color (for example, red, blue, green, and white) (without the toggle of the data signal).

In addition, an example that light emitting diodes RE1 and RE2 representing red are output in the other driving screens will be described with reference to FIGS. 6 to 8.

Referring to FIG. 6, it is confirmed that in the case of a horizontal one-by-one driving screen 1, light emitting diodes RE1 and RE2 of the first pixel PX11 and the second pixel PX12 and light emitting diodes RE1 and RE2 of the fifth pixel PX31 and the sixth pixel PX32 are sequentially output in response to a gate signal.

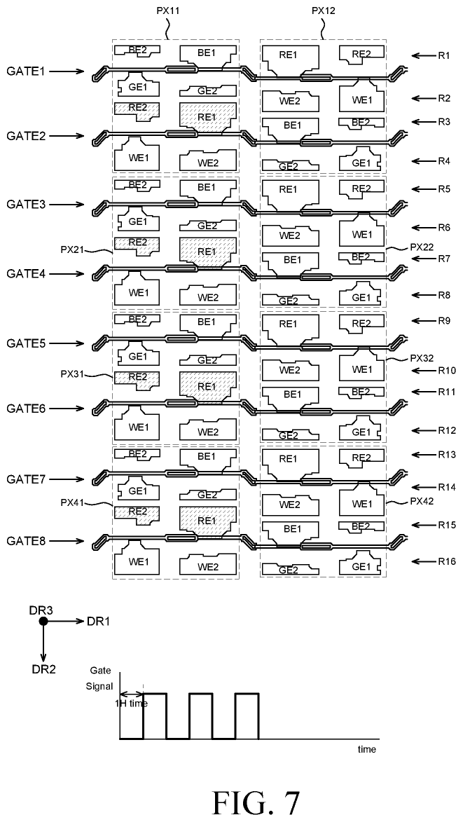

Referring to FIG. 7, it is confirmed that in the case of a vertical one-by-one driving screen, light emitting diodes RE1 and RE2 of the first pixel PX11, the third pixel PX21, the fifth pixel PX31, and the seventh pixel PX41 are sequentially output in response to a gate signal.

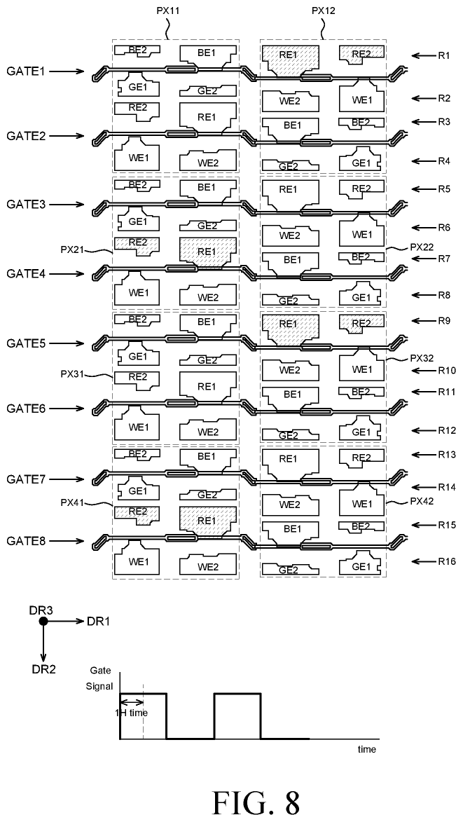

Referring to FIG. 8, it is confirmed that in the case of a dot driving screen, light emitting diodes RE1 and RE2 of the second pixel PX12, the third pixel PX21, the sixth pixel PX32, and the seventh pixel PX41 are sequentially output in response to a gate signal.

The exemplary embodiments of the present disclosure can also be described as follows:

According to an aspect of the present disclosure, a display device includes a display panel in which a plurality of pixels is disposed; a data driver configured to supply a data signal to the pixels; and a gate driver configured to supply a gate signal to the pixels. The panel circuit includes: a plurality of data lines configured to supply the data signal to the pixels; a plurality of gate lines configured to supply the gate signal to the pixels; a high potential voltage line configured to supply a high potential voltage to the pixels; and a reference voltage line configured to supply a reference voltage to the pixels, and the high potential voltage line and the reference voltage line are disposed between a first emission area and a second emission area of sub pixels which configure each of the plurality of pixels.

The reference voltage line may be formed as one wiring line in a lead-in unit and may be divided into two wiring lines between the first emission area and the second emission area.

The pixel may include first to fourth sub pixels and first to fourth circuit elements for driving the first to fourth sub pixels and the data lines include first to fourth data lines for supplying a data signal to the first to fourth circuit elements, respectively.

At least some of the first and second data lines may be disposed between the first circuit element and the second circuit element and at least some of the third and fourth data lines is disposed between the third circuit element and the fourth circuit element.

The high voltage reference line and two or more gate lines may intersect in two or more points and two or more points may include a first point and a second point, and the first circuit element and the fourth circuit element may be disposed in an opposite position with respect to the first point and the second circuit element and the third circuit element may be disposed in an opposite position with respect to the second point.

The gate line may be disposed to be divided into two or more wiring lines in a section intersecting the other wiring line and may be disposed as one wiring line in a no-intersecting section.

The other wiring line may include at least one of the high potential voltage line, the reference voltage line, and the first to fourth data lines.

A first pixel disposed in one side and a second pixel disposed in the other side may have an asymmetric structure with respect to the first and second data lines.

A data signal which is supplied through at least some of the first data lines may be transmitted to the first circuit element across the second data line and a data signal which is supplied through the remaining part of the first data lines may be transmitted to the first circuit element regardless of the second data line.

The first and fourth sub pixels may be defined as a first sub pixel group, the second and third sub pixels are defined as a second sub pixel group, and the first sub pixel group and the second sub pixel group have different areas.

The first pixel may have a structure in which the first sub pixel group and the second sub pixel group are sequentially disposed along a second direction and the second pixel has a structure in which the second sub pixel group and the first sub pixel group are sequentially disposed along the second direction, a first gate line, among the gate lines, is disposed between first and fourth sub pixels of the first pixel and between second and third sub pixels of the second pixel, and a second gate line, among the gate lines, is disposed between first and fourth sub pixels of the second pixel and between second and third sub pixels of the first pixel.

The first gate line and the second gate line may be disposed to be parallel to each other along a first direction which is perpendicular to the second direction.

A gate line in the first pixel and a gate line in the second pixel may be electrically connected while forming a predetermined inclination angle.

The first emission area may have a larger area than the second emission area.

Each sub pixel may include a light emitting diode, and an anode of the light emitting diode includes a first part corresponding to a first emission area, a second part corresponding to a second emission area, and a third part which connects the first part and the second part.

The third part connects the first part and the second part may across the high potential voltage line.

A width of the third part may be smaller than widths of the first and second parts.

The third part may be disconnected to shut off a power to the first part.

The sub pixels may extend along a first direction, at least four sub pixels are sequentially disposed along a second direction perpendicular to the first direction to configure one pixel, pixels disposed in a k-th column (k is 2i−1, and i is a natural number) and pixels disposed in a k+2-th column are disposed to have sub pixels which are disposed in the same manner, and pixels disposed in a k-th column and pixels disposed in a k+1-th column are disposed to have sub pixels which are disposed in different manners.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including a plurality of pixels;
a data driver configured to supply a data signal to the plurality of pixels; and
a gate driver configured to supply a gate signal to the plurality of pixels,
wherein the display panel includes:
a plurality of data lines configured to supply the data signal to the plurality of pixels;
a plurality of gate lines configured to supply the gate signal to the plurality of pixels;
a high potential voltage line configured to supply a high potential voltage to the plurality of pixels; and
a reference voltage line configured to supply a reference voltage to the plurality of pixels,
wherein the high potential voltage line and the reference voltage line are between a first emission area and a second emission area of each of a plurality of sub pixels included in at least a first pixel of the plurality of pixels.

2. The display device according to claim 1, wherein the reference voltage line comprises one wiring line in a lead-in unit and is divided into a plurality of wiring lines between the first emission area and the second emission area, the plurality of wiring lines connected to the one wiring line.

3. The display device according to claim 1, wherein the plurality of sub pixels of each of the plurality of pixels includes a first sub pixel, a second sub pixel, a third sub pixel, a fourth sub pixel, a first circuit element configured to drive the first sub pixel, a second circuit element configured to drive the second sub pixel, a third circuit element configured to drive the third sub pixel, and a fourth circuit element configured to drive the fourth sub pixel, and
wherein the plurality of data lines include a first data line configured to supply a first data signal to the first circuit element, a second data line configured to supply a second data signal to the second circuit element, a third data line configured to supply a third data signal to the third circuit element, and a fourth data line configured to supply a fourth data signal to the fourth circuit element.

4. The display device according to claim 3, wherein at least one of the first data line and the second data line is between the first circuit element of the first pixel and the second circuit element of a second pixel from the plurality of pixels, and at least one of the third data line and the fourth data line is between the third circuit element of the first pixel and the fourth circuit element of a third pixel.

5. The display device according to claim 3, wherein the high potential voltage line and two or more gate lines intersect at a first point and a second point in a plan view of the display device, and the first point is between the first circuit element and the fourth circuit element in the plan view, and the second point is between the second circuit element and the third circuit element in the plan view.

6. The display device according to claim 3, wherein a gate line from the plurality of gate lines is divided into two or more wiring lines in a first section where the gate line intersects the high potential voltage line and the gate line has one wiring line in a second section where the gate line is non-intersecting with the high potential voltage line.

7. The display device according to claim 6, wherein the first section where the gate line intersects the high potential voltage line also includes at least one of the reference voltage line, and the first data line, the second data line, the third data line, and the fourth data line.

8. The display device according to claim 3, wherein the first pixel is at a first side of the first data line and the second data line, and a second pixel is at a second side of the first data line and the second data line, and the first pixel and the second pixel have asymmetric structures with respect to the first data line and the second data line.

9. The display device according to claim 8, wherein a data signal supplied by the first data line is transmitted to the first circuit element via a bridge that crosses the second data line in a plan view of the display device, and the data signal supplied by the first data line is transmitted to the first circuit element of the second pixel without the bridge.

10. The display device according to claim 3, wherein the first sub pixel and the fourth sub pixel are a first sub pixel group having a first area, the second sub pixel and the third sub pixel are a second sub pixel group having a second area that is different from the first area.

11. The display device according to claim 10, wherein the first pixel has a structure in which the first sub pixel group and the second sub pixel group are sequentially disposed along a second direction, and a second pixel has a structure in which the second sub pixel group and the first sub pixel group are sequentially disposed along the second direction in a plan view of the display device,
a first gate line, among the plurality of gate lines, is between a first sub pixel and a fourth sub pixel of the first pixel and between a second sub pixel and a third sub pixel of the second pixel, and
a second gate line, among the plurality of gate lines, is between a first sub pixel and a fourth sub pixel of the second pixel and between a second sub pixel and a third sub pixel of the first pixel.

12. The display device according to claim 11, wherein the first gate line and the second gate line are parallel to each other along a first direction which is different from the second direction.

13. The display device according to claim 11, wherein a gate line in the first pixel and a gate line in the second pixel are electrically connected and have a predetermined inclination angle with respect to a first direction that is different from the second direction.

14. The display device according to claim 1, wherein the first emission area is a larger than the second emission area.

15. The display device according to claim 1, wherein each of the plurality of sub pixels includes a light emitting diode having an anode electrode, the anode electrode including a first part corresponding to the first emission area, a second part corresponding to the second emission area, and a third part that connects the first part and the second part.

16. The display device according to claim 15, wherein the third part connects the first part and the second part across the high potential voltage line in a plan view of the display device.

17. The display device according to claim 15, wherein a width of the third part is less than a width of the first part and a width of the second part.

18. The display device according to claim 15, wherein the third part is configured to be disconnected such that power is no longer supplied to the first part.

19. The display device according to claim 1, wherein the plurality of sub pixels extends along a first direction, at least four sub pixels are sequentially disposed along a second direction perpendicular to the first direction to configure one pixel, pixels disposed in odd columns are arranged in a first arrangement, and pixels disposed in even columns are arranged in a second arrangement that is different from the first arrangement.

20. A display device, comprising:
a display panel including a plurality of pixels, a high potential voltage line configured to supply a high potential voltage to the plurality of pixels, and a reference voltage line configured to supply a reference voltage to the plurality of pixels;
a data driver configured to supply data signals to the plurality of pixels; and
a gate driver configured to supply gate signals to the plurality of pixels,
wherein a pixel from the plurality of pixels includes a plurality of sub pixels configured to emit different colors of light, each sub pixel including a first emission area and a second emission area that is electrically connected to the first emission area and emits a same color of light as the first emission area,
wherein the reference voltage line and the high potential voltage line are between the first emission area and the second emission area of each of the plurality of sub pixels of the pixel in a plan view of the display device.

21. The display device of claim 20, wherein first emission area of each of the plurality of sub pixels is larger than the second emission area of the sub pixel.

22. The display device of claim 21, wherein each of the plurality of sub pixels includes a light emitting diode having an anode electrode, the anode electrode including a first part corresponding to the first emission area and a second part corresponding to the second emission area.

23. The display device of claim 22, wherein the anode electrode further comprises:
a third part that connects together the first part and the second part, the third part overlapping the reference voltage line and the high potential voltage line in the plan view.

24. The display device according to claim 23, wherein a width of the third part is less than a width of the first part and a width of the second part.

25. The display device of claim 23, wherein each of the plurality of sub pixels of the pixel includes a corresponding circuit element that is connected to the second part of the anode electrode of the sub pixel that corresponds to the second emission area of the sub pixel to provide power to the anode electrode, and the first part of the anode electrode of the sub pixel receives the power from the second part of the anode electrode of the sub pixel via the third part of the anode electrode.
